(19) United States
(12) Patent Application Publication
(10) Pub. No.: US 2023/0323560 A1
(43) Pub. Date: Oct. 12, 2023

(54) Graphite Crucible for Mono-crystal Furnace and Manufacturing Method Therefor, Crucible Assembly, and Mono-crystal Furnace

(71) Applicant: ZHONGHUAN ADVANCED SEMICONDUTOR MATERIALS CO., LTD., Jiangsu (CN)

(72) Inventors: Shuangli WANG, Xuzhou, Jiangsu (CN); Chun-hung CHEN, Taiwan (CN)

(21) Appl. No.: 18/022,274

(22) PCT Filed: Dec. 17, 2021
(86) PCT No.: PCT/CN2021/139236

§ 371 Date: Feb. 21, 2023

(30) Foreign Application Priority Data
Dec. 21, 2020 (CN) 202011519963.4

(51) Int. Cl. C30B 15/10

(52) U.S. Cl. CPC C30B 15/10

(57) ABSTRACT

A graphite crucible for a mono-crystal furnace and a manufacturing method therefor, a crucible assembly, and a mono-crystal furnace. A groove is formed at a cutting portion. A thermal field simulation is performed on a semi-finished crucible product, a quartz crucible matching with the semi-finished crucible product and a melt to obtain an isotherm of a high temperature region of the melt. The shape of the groove is consistent with the shape of a part of the isotherm in a longitudinal section of a main body. The semi-finished crucible product is constructed such that the groove is produced on an inner wall of the semi-finished crucible product to form the main body.

### CROSS-REFERENCE TO RELATED APPLICATION

The disclosure is based upon and claims priority to Chinese Patent Application No. 202011519963.4 on Dec. 21, 2020, and the disclosure of which is hereby incorporated by reference in its entirety.

### TECHNICAL FIELD

The disclosure relates to the technical field of crucibles, and in particular, to a graphite crucible for a mono-crystal furnace and a manufacturing method therefor, a crucible assembly, and a mono-crystal furnace.

### BACKGROUND

In the related art, a crucible assembly in a mono-crystal furnace includes a quartz crucible and a graphite crucible. The crucible assembly contains a raw material. Under the heating action of a heater in the mono-crystal furnace, the raw material in the crucible assembly is melted into a silicon melt. Oxygen in the silicon melt is mainly from the quartz crucible. If the oxygen content in the melt is excessively high, large amount of OISF and oxygen precipitates occur in a crystal. In particular, since the temperature at an edge portion of the silicon melt is relatively high, there is more oxygen dissolved at the edge portion of the silicon melt throughout a crystal growth process, resulting in excessively high oxygen content at the edge of the silicon melt, especially without an external magnetic field apparatus, a segregation phenomenon occurs, affecting the quality of the crystal.

### SUMMARY

The disclosure is intended to resolve at least one of the technical problems in the related art. To this end, some embodiments of the disclosure provide a graphite crucible for a mono-crystal furnace. The graphite crucible reduces heat conducted and radiated by a heater to a high temperature region of a melt, and reduce a temperature at an edge of the melt, so that the oxygen content in the melt is reduced, and the quality of an ingot is enhanced.

An embodiment mode of the disclosure further provides a crucible assembly having the graphite crucible.

An embodiment mode of the disclosure further provides a mono-crystal furnace having the crucible assembly.

An embodiment mode of the disclosure further provides a method for manufacturing a graphite crucible.

A first aspect of the disclosure provides a graphite crucible for a mono-crystal furnace. The graphite crucible includes a main body. The main body is a graphite member and provided with a containing cavity. A wall of the containing cavity is provided with a cutting portion. A groove is formed in the cutting portion, and extends in a circumferential direction of the main body to form an annular structure. Thermal field simulation is performed on a semi-finished crucible product, a quartz crucible matching the semi-finished crucible product, and a melt contained in the quartz crucible, to obtain an isotherm of a high temperature region of the melt. A shape of the groove is consistent with a shape of a part of the isotherm in a longitudinal section of the main body. The semi-finished crucible product is constructed to process the groove in an inner wall of the semi-finished crucible product so as to form the main body; and a temperature of the high temperature region is higher than a temperature of any other region of the melt.

According to the graphite crucible for a mono-crystal furnace in the disclosure, by means of performing thermal field simulation on the semi-finished crucible product, the quartz crucible and the melt to accurately obtain the isotherm of the high temperature region of the melt, and forming the groove in the cutting portion according to the shape of the isotherm, when the graphite crucible is applied to the mono-crystal furnace, the heat conducted and irradiated to the high temperature region of the melt is reduced insofar as guaranteeing the structural strength of the graphite crucible, so as to achieve an effect of weakening heat conduction. Therefore, the temperature at the edge of the melt is reduced, the oxygen content of the melt is decreased, and the quality of the crystal is effectively enhanced.

In some embodiments, the graphite crucible is configured to pull a crystal by means of a Czochralski technique. During crystal pulling, a plurality of isotherms are arranged from top to bottom with the decreasing of a liquid level of the melt. Region on the wall of the semi-finished crucible product corresponding to the plurality of isotherms are cutting region. A plurality of cutting portions are located in the cutting region.

In some embodiments, the plurality of cutting portions are spaced apart from each other in an axial direction of the main body, and respectively correspond to the plurality of isotherms. Each cutting portion of the plurality of cutting portions is formed with the groove. The shape of the groove is consistent with the shape of the part of the corresponding isotherm of the plurality of isotherms.

In some embodiments, the cutting portion is flush with an upper end portion of the corresponding isotherm of the plurality of isotherms.

In some embodiments, the main body includes a sidewall portion and a bottom wall portion. The sidewall portion is formed into a cylindric structure. The bottom wall portion is connected to a bottom of the sidewall portion to close the bottom of the sidewall portion. The groove is formed in the sidewall portion and/or the bottom wall portion.

In some embodiments, a thermal insulation member is filled in the groove. Thermal conductivity of the thermal insulation member is lower than thermal conductivity of the main body.

In some embodiments, the thermal insulation member is a carbon fiber material member.

In some embodiments, the shape of the groove is consistent with a shape of the upper end portion of the isotherm.

A second aspect of the disclosure provides a crucible assembly. The crucible assembly includes: a graphite crucible, where the graphite crucible is the graphite crucible for a mono-crystal furnace according to the first aspect of the disclosure; and a quartz crucible, mounted in the containing cavity of the graphite crucible.

According to the crucible assembly of the disclosure, by means of the graphite crucible, the heat conducted and radiated by the heater to the high temperature region of the melt is reduced, and the temperature at the edge of the melt is decreased, so that the oxygen content in the melt is reduced, and the quality of an ingot is enhanced.

A third aspect of the disclosure provides a mono-crystal furnace. The mono-crystal furnace includes: a furnace body; and a crucible assembly. The crucible assembly is the crucible assembly according to the second aspect of the disclosure and is disposed in the furnace body.

According to the mono-crystal furnace of the disclosure, by means of the crucible assembly, the temperature at the edge of the melt is decreased, so that the oxygen content in the melt is reduced, and the quality of the ingot is enhanced.

A fourth aspect of the disclosure provides a method for manufacturing a graphite crucible. The graphite crucible is the graphite crucible for a mono-crystal furnace according to the first aspect of the disclosure. The manufacturing method includes the following steps: S1: performing thermal field simulation on the semi-finished crucible product, the quartz crucible matching the semi-finished crucible product, and the melt contained in the quartz crucible; S2: extracting a simulation result in S1, to obtain the isotherm of the high temperature region of the melt, wherein the temperature of the high temperature region is higher than the temperature of any other region of the melt; and S3: determining the shape of the groove on the longitudinal section of the semi-finished crucible product according to the shape of the isotherm, and processing the groove in a cutting portion to form the main body.

According to the method for manufacturing a graphite crucible in the disclosure, by means of performing thermal field simulation on the semi-finished crucible product, the quartz crucible and the melt to accurately obtain the isotherm of the high temperature region of the melt, and determining the shape of the groove according to the isotherm, the heat conducted and irradiated to the high temperature region of the melt is effectively reduced, and the temperature at the edge of the melt is reduced, so that the oxygen content of the melt is decreased, and the quality of the ingot is enhanced.

In some embodiments, in S1, the semi-finished crucible product is configured to pull a crystal by means of a Czochralski technique for thermal field simulation, to obtain a plurality of isotherms in S2. The plurality of isotherms are arranged from top to bottom with the decreasing of a liquid level of the melt. Region on a wall of the semi-finished crucible product corresponding to the plurality of isotherms are cutting region. S3 further includes determining a position of the cutting portion in the cutting region.

In some embodiments, the step of determining the position of the cutting portion in the cutting region includes: importing the plurality of isotherms into a drawing of the semi-finished crucible product, to determine the cutting region; and selecting a part of the plurality of isotherms, and determining the position of the cutting portion according to the position of the selected isotherm of the plurality of isotherms.

Additional aspects and advantages of the disclosure will be partially set forth in the following description, and in part will be apparent from the following description, or is learned by practice of the disclosure.

### BRIEF DESCRIPTION OF THE DRAWINGS

The above and/or additional aspects and advantages of the disclosure becomes apparent and readily understood from the following description of the embodiments with reference to the accompanying drawings.

FIG. 1 is a schematic diagram of a graphite crucible according to an embodiment of the disclosure.

FIG. 2 is an enlarged view of a part A framed in FIG. 1.

FIG. 3 is a schematic diagram of a crucible assembly according to an embodiment of the disclosure.

FIG. 4 is a partial enlarged view of the crucible assembly shown in FIG. 3.

FIG. 5 is a schematic diagram of an isotherm in a high temperature region when a melt in the crucible assembly shown in FIG. 3 is heated.

FIG. 6 is a schematic flowchart of a method for manufacturing a graphite crucible according to an embodiment of the disclosure.

FIG. 7 is a schematic diagram of a groove processed in a semi-finished crucible product shown in FIG. 6.

FIG. 8 is a schematic flowchart of a method for manufacturing a graphite crucible according to another embodiment of the disclosure.

FIG. 9 is a schematic diagram of a result of thermal field simulation performed on a semi-finished crucible product (that is, Solution I, without disposing a groove), a graphite crucible (Solution II) that is provided with the groove and a thermal insulation member filled in the groove in the disclosure, and a graphite crucible (Solution III) that is provided with the groove and not filled with a material member in the groove in the disclosure.

FIG. 10 is a comparison diagram of isotherms of three solutions in a high temperature region shown in FIG. 9.

FIG. 11 is a comparison diagram showing distribution of inner wall temperatures of the crucibles of Solution I and Solution II shown in FIG. 9.

FIG. 12 is a comparison diagram of oxygen content at edges of melts of Solution I and Solution II shown in FIG. 9.

In the drawings:

Crucible assembly 1000; Quartz crucible 200; Melt 300; Isotherm R;

Graphite crucible 100; Central axis L; Semi-finished crucible product 101; Semi-finished product cavity 101a;

Main body 1; Cutting portion 10; Containing cavity 1a; Groove 1b; Cavity portion 1c;

Sidewall portion 11; Bottom wall portion 12.

### DETAILED DESCRIPTION OF THE EMBODIMENTS

Embodiments of the disclosure are described in detail below. Examples of the embodiments are shown in the accompanying drawings, where the same or similar reference numerals throughout the disclosure represent the same or similar elements or the elements having the same or similar functions. The embodiments described below with reference to the accompanying drawings are exemplary and are merely used to explain the disclosure, but should not be construed as a limitation on the disclosure.

The following disclosure provides many different embodiments or examples for implementing different structures of the disclosure. In order to simplify the disclosure of the disclosure, components and settings of specific examples are described below. Definitely, the above are merely examples and are not intended to limit the disclosure. Furthermore, the disclosure may repeat reference numerals and/or letters in different examples. The repetition is for simplicity and clarity, which itself does not indicate a relationship between the embodiments and/or configurations discussed. In addition, examples of various specific processes and materials are provided in the disclosure, but the ordinary skill in the art may recognize the applicability of other processes and/or the use of other materials.

A graphite crucible 100 for a mono-crystal furnace according to an embodiment of the disclosure is described below with reference to the accompanying drawings.

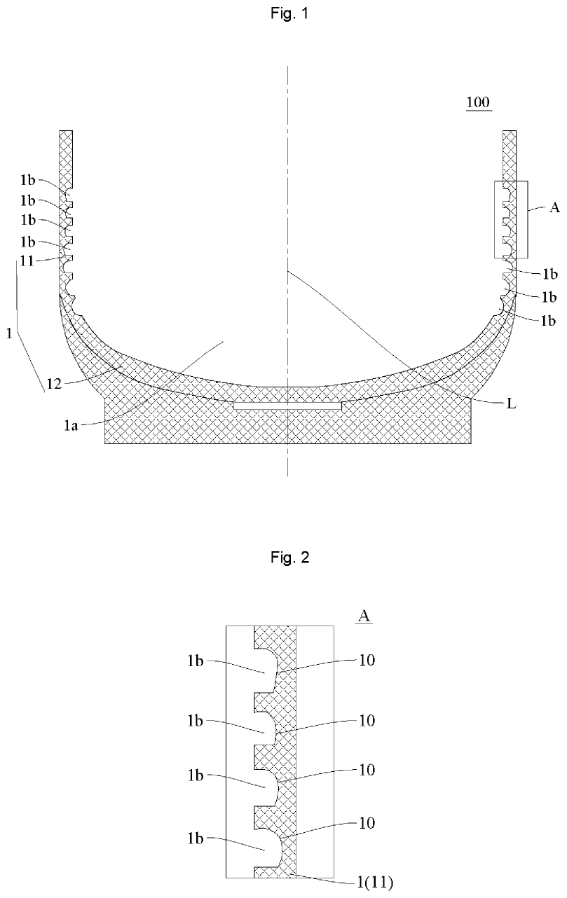

As shown in FIG. 1, the graphite crucible 100 includes a main body 1. The main body 1 is a graphite member, and provides a containing cavity 1a. The containing cavity 1a is configured to contain a raw material. After being heated, the raw material in the containing cavity 1a is melted into a melt 300. A wall of the containing cavity 1a is provided with a cutting portion 10, and a groove 1b is formed at the cutting portion 10. The groove 1b is formed in an inner wall of the main body 1, and is formed by a partial dented wall of the containing cavity 1a. The groove 1b extends in a circumferential direction of the graphite crucible 100 to form an annular structure, so that the structural strength of the graphite crucible 100 is guaranteed.

It is to be noted that, the graphite crucible 100 has a central axis L. In the description of the disclosure, an axial direction of the main body 1 is a direction along the central axis L of the graphite crucible 100. A circumferential direction of the main body 1 is a direction around the central axis L of the graphite crucible 100. For example, in an example of FIG. 1, the graphite crucible 100 is formed into a revolving body structure. A rotatory central line of the revolving body structure is the central axis L of the graphite crucible 100. Definitely, a shape of the graphite crucible 100 is not limited thereto.

Thermal field simulation is performed on a semi-finished crucible product 101, a quartz crucible 200 matching the semi-finished crucible product 101, and a melt 300 contained in the quartz crucible 200, to obtain an isotherm R of a high temperature region of the melt 300. A shape of the groove 1b is consistent with a shape of a part of the isotherm R in a longitudinal section of the main body 1. The semi-finished crucible product 101 is constructed to process the groove 1b in an inner wall of the semi-finished crucible product 101 so as to form the main body 1. The semi-finished crucible product 101 is a graphite member and defines a semi-finished product cavity 101a. Then the main body 1 is formed by processing the groove 1b in the wall of the semi-finished product cavity 101a. Definitely, the semi-finished product cavity 101a corresponds to the containing cavity 1a. A difference between the semi-finished product cavity 101a and the containing cavity 1a lies in that whether the groove 1b is formed in the wall. In addition, a temperature of the high temperature region is higher than a temperature of any other region of the melt 300, so that the high temperature region is a region where the temperature of the melt 300 is the highest. The high temperature region is located at an edge of the melt 300.

It is understood that, after the groove 1b is processed in the semi-finished crucible product 101, a central axis of the semi-finished crucible product 101 is formed as the central axis of the main body 1. The longitudinal section of the main body 1 is understood as a plane passing through the central axis L of the graphite crucible 100.

When the graphite crucible 100 is applied to a mono-crystal furnace, the quartz crucible 200 adapts to be mounted in the containing cavity 1a, and the raw material adapts to be placed in the quartz crucible 200. When the mono-crystal furnace operates, a heater in the mono-crystal furnace heats the graphite crucible 100, the quartz crucible 200, and the raw material in the quartz crucible 200, to cause the raw material to be melt into the melt 300. Since the heater is disposed on a radial outer side and/or a bottom side of the graphite crucible 100, a temperature of the high temperature region at an edge (outer side edge and/or bottom side edge) of the melt 300 is the highest, resulting in excessively high oxygen content at the edge of the melt 300. In the disclosure, by disposing the cutting portion 10 on the wall of the containing cavity 1a and forming the groove 1b at the cutting portion 10, and when the quartz crucible 200 is mounted to the graphite crucible 100, the outer wall of the quartz crucible 200 cannot be in contact with or attached to the wall of the groove 1b, so that the quartz crucible 200 and the groove 1b may define a cavity portion 1c (as shown in FIG. 4), and thermal conductivity of the cavity portion 1c is obviously lower than the thermal conductivity of the graphite. That is to say, the thermal conductivity of the cavity portion 1c is obviously lower than the thermal conductivity of the main body 1. Therefore, heat conducted and irradiated to the edge of the melt 300 by the heater is reduced, and the temperature at the edge of the melt 300 is decreased. Due to a crystal growth process, the quartz crucible decomposes into oxygen atoms and silicon atoms in a high temperature environment and enters the melt, so that an oxygen dissolution rate at the edge of the melt 300 is slowed down, and the oxygen content is reduced, thereby enhancing the quality of an ingot.

In addition, a shape of the groove 1b is consistent with a shape of a part of the isotherm R of the high temperature region in a longitudinal section of the main body 1, so that the shape of the groove 1b is designed according to the shape of the isotherm R of the high temperature region. In this way, the groove 1b may match the high temperature region, to effectively reduce a region area of the high temperature region, so as to further effectively reduce the heat conducted and irradiated to the high temperature region of the melt 300 by the heater, slow down the oxygen dissolution rate at the high temperature region of the melt 300 and reduce the oxygen content. Therefore, the quality of the ingot is enhanced, and the structural strength of the graphite crucible 100 cannot be weakened excessively. Since the isotherm of each thermal field is different, in the disclosure, by means of performing simulation on the semi-finished crucible product 101, the quartz crucible 200 and the melt 300, the isotherm R of the high temperature region of the melt 300 is accurately obtained, so that the shape of the groove 1b is accurately obtained. Therefore, that a certain place belongs to a high temperature region but is actually not in the high temperature region due to experience is avoided from affecting the thermal field structure of the mono-crystal furnace, which then affects the crystallization rate of the ingot, thereby facilitating the disclosure to ensure the crystallization rate of the ingot.

Therefore, according to the graphite crucible 100 for a mono-crystal furnace in this embodiment of the disclosure, by means of performing thermal field simulation on the semi-finished crucible product 101, the quartz crucible 200 and the melt 300 to accurately obtain the isotherm R of the high temperature region of the melt 300, so as to accurately obtain the shape of the groove 1b, when the graphite crucible 100 is applied to the mono-crystal furnace, the heat conducted and irradiated to the high temperature region of the melt 300 is reduced insofar as guaranteeing the structural strength of the graphite crucible 100, so as to achieve an effect of weakening heat conduction. Therefore, the temperature of the high temperature region of the melt 300 is reduced, the temperature at the edge of the melt 300 is reduced, and the oxygen content of the melt 300 is decreased, thereby effectively enhancing the quality of the crystal.

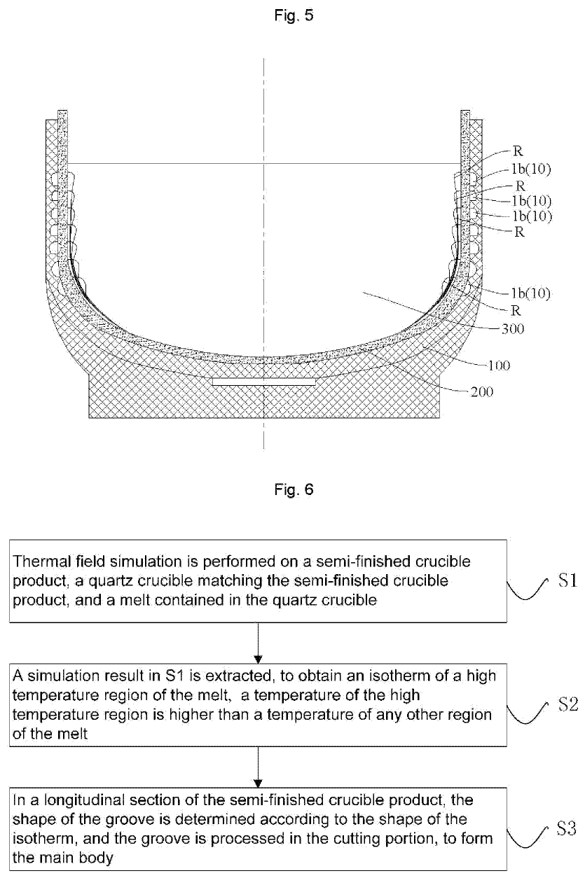

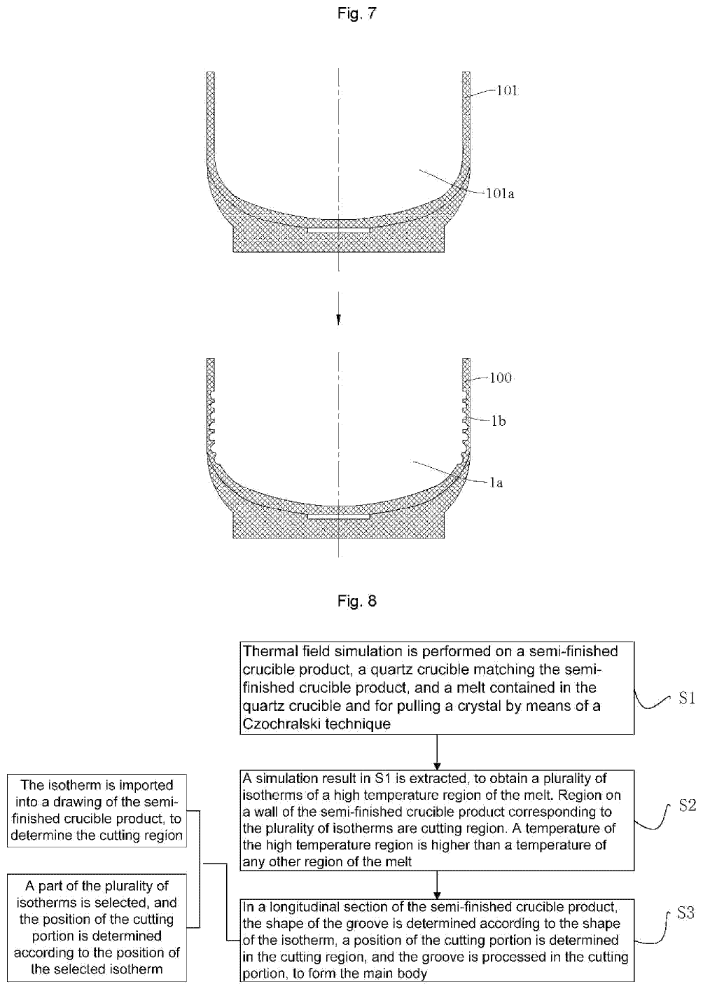

In some embodiments, as shown in FIG. 5, the graphite crucible 100 is configured to pull the crystal by means of a Czochralski technique. During crystal pulling, a liquid level of the melt 300 gradually decreases. At different phases or moments, a position of the isotherm R of the high temperature region is different, so that there are a plurality of isotherms R throughout the crystal pulling process. The plurality of isotherms R are arranged from top to bottom with the decreasing of the liquid level of the melt 300. Region on the wall of the semi-finished crucible product 101 corresponding to the plurality of isotherms R are cutting region, or regions of the wall of the semi-finished crucible product 101 that are covered by the plurality of isotherms R in a radial direction of the semi-finished crucible product 101 are the cutting region. A plurality of cutting portions 10 are located in the cutting region, so that the designing of the positions of the cutting portions 10 is simplified. In addition, a plurality of grooves 1b may also be located in the cutting region, to effectively ensure that different grooves 1b play a role of weakening heat conduction at different phases, so that throughout the crystal pulling process, the grooves 1b may weaken heat conduction.

It is understood that, throughout the crystal pulling process, if a length of the ingot changes continuously, the isotherm R also changes continuously, so that there are countless isotherms R. The above Czochralski technique is also called a Czochralski method, and is a (Czochralski) CZ method, a continuous CZ (CCZ) method, a Magnetic CZ (MCZ) method, or the like.

For example, the main body 1 includes a sidewall portion 11 and a bottom wall portion 12. The sidewall portion 11 is formed into a cylindric structure. The bottom wall portion 12 is connected to a bottom of the sidewall portion 11 to close the bottom of the sidewall portion 11. When the heater of the mono-crystal furnace is only disposed on the radial outer side of the sidewall portion 11, the high temperature region is located at the edge of the radial outer side of the melt 300, so that the plurality of isotherms R are all disposed corresponding to the sidewall portion 11. In this case, the plurality of isotherms R is successively arranged from top to bottom in an axial direction of the main body 1, the cutting region are located on the sidewall portion 11, and the grooves 1b are only formed in the sidewall portion 11. When the heater of the mono-crystal furnace is only disposed on a lower side of the bottom wall portion 12, the high temperature region is located at the bottom edge of the melt 300, so that the plurality of isotherms R are arranged corresponding to the bottom wall portion 12. Since a middle portion of a curved surface corresponding to the inner wall of the bottom wall portion 12 is dented downward, the plurality of isotherms R may still be successively arranged from top to bottom with the decreasing of the liquid level of the melt 300, so that the cutting region are located on the bottom wall portion 12, and the grooves 1b are only formed in the bottom wall portion 12. When the heater of the mono-crystal furnace includes a first heater disposed on the radial outer side of the sidewall portion 11 and a second heater disposed on the bottom side of the bottom wall portion 12, the high temperature region is located at the edge of the radial outer side of the melt 300. If the second heater is relatively large in power, the high temperature region is also located at the bottom edge of the melt 300. In this case, the plurality of isotherms R are arranged corresponding to the sidewall portion 11 and the bottom wall portion 12, and are successively arranged from top to bottom. The cutting region are located on the sidewall portion 11 and the bottom wall portion 12, and the grooves 1b are respectively formed in the sidewall portion 11 and the bottom wall portion 12.

It is understood that, the groove 1b is dented in a thickness direction of the main body 1, or the groove 1b is dented in a radial direction of the main body 1. For example, when the groove 1b is formed in the sidewall portion 11, the groove 1b is dented in a thickness direction of the sidewall portion 11; and when the groove 1b is formed in the bottom wall portion 12, the groove 1b is concave and convex formed in a thickness direction of the bottom wall portion 12.

In some embodiments, as shown in FIG. 4 and FIG. 5, the plurality of cutting portions 10 are spaced apart from each other in an axial direction of the main body 1. The plurality of cutting portions 10 respectively correspond to the plurality of isotherms R. The groove 1b is formed in each cutting portion 10, so that there are a plurality of grooves 1b. In this way, the plurality of grooves 1b are spaced apart from each other in the axial direction of the main body 1, so that the structural strength of the graphite crucible 100 is guaranteed, and the weakening effect of the grooves 1b on the main body 1 is reduced. There is a spacing bulge between the two adjacent grooves 1b. An end surface of a free end of the spacing bulge and walls of other walls in which the containing cavities 1a of the grooves 1b are not formed are located on a same smooth curved surface.

For example, when the cutting portion 10 is only formed on the sidewall portion 11 of the main body 1, the plurality of cutting portions 10 are spaced apart from each other in the axial direction of the main body 1. When the cutting portion 10 is only formed on the bottom wall portion 12 of the main body 1, since a middle portion of a curved surface corresponding to the inner wall of the bottom wall portion 12 is dented downward, the cutting portions 10 may also be spaced apart from each other in the axial direction of the main body 1. When the cutting portions 10 are respectively formed on the sidewall portion 11 and the bottom wall portion 12, all of the cutting portions 10 is spaced apart from each other in the axial direction of the main body 1. Definitely, there is one cutting portion 10, and in this case, the number of the grooves 1b is one.

It is understood that, insofar as meeting a strength requirement of the graphite crucible 100, a depth of the groove 1b in the radial direction of the main body 1 is as small as possible, and a width of the groove 1b in the axial direction of the main body 1 is as large as possible, so that the capacity of the groove 1b for weakening heat conduction is effectively enhanced. A temperature difference between any two adjacent isotherms in the plurality of isotherms R of the selected high temperature region is specifically set according to an actual application. A specific temperature value corresponding to each isotherm R is specifically set according to the actual application. In the description of the disclosure, the meaning of “a plurality of” is two or more.

The shape of the groove 1b is consistent with the shape of the part of the corresponding isotherm R. For example, a portion of isotherms R are selected. The positions of the plurality of cutting portions 10 is in one-to-one correspondence with the positions of the portion of isotherms R, so that the position of each groove 1b may correspond to the position of the corresponding isotherm R. For example, in the axial direction of the semi-finished crucible product 101, the position of the cutting portion 10 is flush with an upper end portion of the corresponding isotherm R, so that the position of the groove 1b is determined according to the isotherm R. Therefore, the design of the position of the groove 1b is simplified. The shape of the groove is consistent with the shape of the portion the corresponding isotherm. Since the shapes of the plurality of isotherms R corresponding to the plurality of cutting portions 10 are generally different, by determining the shape of the corresponding groove according to the shape of the isotherm, the shape of the groove is more in line with actual production.

In some embodiments, as shown in FIG. 1 and FIG. 5, the cutting portion 10 is flush with the upper end portion of the corresponding isotherm R. For example, the top end of the cutting portion 10 is flush with the top end of the corresponding isotherm R, so as to rapidly determine the position of the cutting portion 10 according to the position of the selected isotherm R. In addition, the heater of the mono-crystal furnace includes a portion disposed on the radial outer side of the graphite crucible 100. There is a protrusion on the upper end of the isotherm R of the high temperature region of the melt 300. The cutting portion 10 is correspondingly disposed with the protrusion, so as to effectively reduce the temperature at the edge of the melt 300. Therefore, the oxygen content of the melt 300 is reduced.

For example, when the cutting portion 10 is formed on the sidewall portion 11 of the main body 1, the corresponding isotherm R is arranged corresponding to the sidewall portion 11. The trend of the isotherm R is related to the inner wall shape of the sidewall portion 11. The overall trend of each isotherm R extends from top to bottom, so that the cutting portion 10 is flush with the upper end portion of the corresponding isotherm R. When the cutting portion 10 is formed on the bottom wall portion 12 of the main body 1, the corresponding isotherm R is arranged corresponding to the bottom wall portion 12. The trend of the isotherm R is related to the inner wall shape of the bottom wall portion 12. Since a middle portion of a curved surface corresponding to the inner wall of the bottom wall portion 12 is dented downward, the overall trend of each isotherm R extends from top to bottom, so that the cutting portion 10 is flush with the upper end portion of the corresponding isotherm R. Definitely, the disposed position of the cutting portion 10 is not limited thereto.

In some embodiments, as shown in FIG. 1, the main body 1 includes a sidewall portion 11 and a bottom wall portion 12. The sidewall portion 11 is formed into a cylindric structure. The bottom wall portion 12 is connected to a bottom of the sidewall portion 11 to close the bottom of the sidewall portion 11. The grooves 1b are formed on the sidewall portion 11 and/or the bottom wall portion 12. For example, when the heater of the mono-crystal furnace is only disposed on the radial outer side of the graphite crucible 100, the groove 1b is formed on the sidewall portion 11. When the heater of the mono-crystal furnace includes a first heater disposed on the radial outer side of the graphite crucible 100 and a second heater disposed on the bottom side of the graphite crucible 100, if the second heater is relatively large in power, the high temperature region is located at the bottom of the graphite crucible 100. In this case, the grooves 1b is respectively formed on the sidewall portion 11 and the bottom wall portion 12. Therefore, the position of the groove 1b is flexibly designed, an actual differentiation requirement is met.

It is to be noted that, in the description of the disclosure, the meaning of “and/or” includes three parallel solutions. For example, “A and/or B” includes an A solution, a B solution, or a solution simultaneously meeting A and B. For example, that the groove 1b is formed on the sidewall portion 11 and/or the bottom wall portion 12 includes: 1, the groove 1b is formed in the sidewall portion 11, and the groove 1b is not formed in the bottom wall portion 12; 2, the groove 1b is not formed in the sidewall portion 11, and the groove 1b is formed in the bottom wall portion 12; and 3, the grooves 1b are respectively formed on the sidewall portion 11 and the bottom wall portion 12.

The “cylindric structure” should be understood in a broad sense, including but not limited to the cylindric structure, a cone tube structure, and a polygonal cylindric structure.

In some embodiments, a thermal insulation member is filled in the groove 1b. Thermal conductivity of the thermal insulation member is lower than thermal conductivity of the main body 1, so as to ensure that the groove 1b may weaken the heat conduction between the heater and the melt 300.

It is understood that, when there is one groove 1b, the groove 1b is filled with the thermal insulation member; and when there are a plurality of grooves 1b, at least one of the plurality of grooves 1b is filled with the thermal insulation member.

Definitely, the groove 1b may alternatively be not filled with other components. When the graphite crucible 100 is applied to the mono-crystal furnace, the quartz crucible 200 is mounted in the containing cavity 1a. In this case, the groove 1b is filled with air, and thermal conductivity of the air is far less than thermal conductivity of graphite, so that the effect of weakening heat conduction may also be achieved.

In some embodiments, the thermal insulation member is a carbon fiber material member. The carbon fiber material member has obvious anisotropy. In a direction perpendicular to a carbon fiber filament, the carbon fiber material member has poor thermal and electrical conductivity, but has desirable thermal insulation. In addition, the carbon fiber material member has desirable high temperature resistance, so that the usage reliability of the carbon fiber material member at a high temperature is guaranteed.

Definitely, the thermal insulation member may also be other material members, and is not limited to the carbon fiber material member.

In some embodiments, as shown in FIG. 5, the upper end portion of the isotherm R has a bending portion to form the protrusion. The shape of the groove 1b is consistent with the shape of the upper end portion of the isotherm R, to achieve the arrangement of the groove 1b.

It is understood that, when the cutting portion 10 is formed on the sidewall portion 11 of the main body 1, the overall trend of the corresponding isotherm R extends from top to bottom, so that the shape of the groove 1b in the sidewall portion 11 is consistent with the shape of the upper end portion of the corresponding isotherm R. When the cutting portion 10 is formed on the bottom wall portion 12 of the main body 1, the overall trend of the corresponding isotherm R extends from top to bottom, so that the shape of the groove 1b in the bottom wall portion 12 is consistent with the shape of the upper end portion of the corresponding isotherm R.

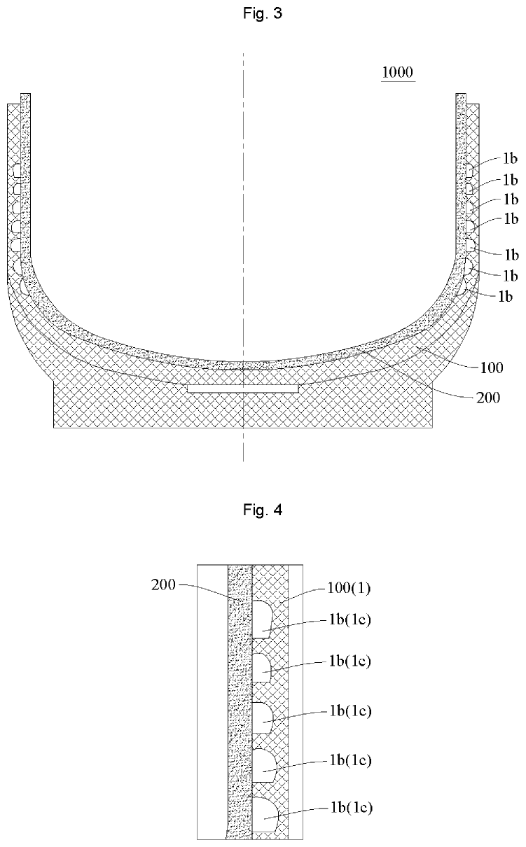

A second aspect of the disclosure provides a crucible assembly 1000. As shown in FIG. 3, the crucible assembly 1000 includes a graphite crucible 100 and a quartz crucible 200. The quartz crucible 200 is mounted in a containing cavity 1a of the graphite crucible 100. The graphite crucible 100 is the graphite crucible 100 for a mono-crystal furnace according to the embodiment of the first aspect of the disclosure.

According to the crucible assembly 1000 in this embodiment of the disclosure, by means of the graphite crucible 100, the temperature at the edge of the melt 300 in the crucible assembly 1000 is reduced insofar as guaranteeing the usage reliability of the crucible assembly 1000. Therefore, the oxygen content of the melt 300 is reduced, thereby effectively enhancing the quality of a crystal.

A third aspect of the disclosure provides a mono-crystal furnace. The mono-crystal furnace includes a furnace body and a crucible assembly 1000. The crucible assembly 1000 is disposed in the furnace body. The crucible assembly 1000 is the crucible assembly 1000 according to the embodiment of the second aspect of the disclosure.

According to the mono-crystal furnace in this embodiment of the disclosure, by means of the crucible assembly 1000, the temperature at the edge of the melt 300 in the crucible assembly 1000 is reduced, so that the oxygen content in the melt 300 is reduced, thereby enhancing the quality of an ingot produced by the mono-crystal furnace.

Other structures and operations of the mono-crystal furnace according to the embodiments of the disclosure are known to those of ordinary skill in the art, and will not be described in detail here.

An embodiment of a fourth aspect of the disclosure provides a method for manufacturing a graphite crucible 100. The graphite crucible 100 is the graphite crucible 100 for a mono-crystal furnace according to the embodiment of the first aspect of the disclosure. The method for manufacturing a graphite crucible 100 includes the following steps.

At S1, thermal field simulation is performed on a semi-finished crucible product 101, a quartz crucible 200 matching the semi-finished crucible product 101, and a melt 300 contained in the quartz crucible 200.

At S2, a simulation result in S1 is extracted, to obtain an isotherm R of a high temperature region of the melt 300. A temperature of the high temperature region is higher than a temperature of any other region of the melt 300, so that the high temperature region is a region where the temperature of the melt 300 is the highest.

At S3, in a longitudinal section of the semi-finished crucible product 101, the shape of the groove 1b is determined according to the shape of the isotherm R, for example, the shape of the groove 1b is consistent with the shape of the upper end portion of the corresponding isotherm R in the longitudinal section of the semi-finished crucible product 101, and the groove 1b is processed in the cutting portion 10, to form the main body 1. Definitely, the semi-finished crucible product 101 is constructed to process the groove 1b in an inner wall of the semi-finished crucible product 101 so as to form the main body 1. The quartz crucible 200 may also match the graphite crucible 100 in the disclosure.

Herein, it is to be noted that, the steps may have a sequence, and in the same step, the sequence of actions is not fixed. For example, S1, S2 and S3 are performed successively, so that “thermal field simulation” in S1 is before “the obtaining of the isotherm R” in S2.

Therefore, according to the method for manufacturing a graphite crucible 100 in this embodiment of the disclosure, by means of performing thermal field simulation on the semi-finished crucible product 101, the quartz crucible 200 and the melt 300 to accurately obtain the isotherm R of the high temperature region of the melt 300, and determining the shape of the groove 1b according to the isotherm R, the heat conducted and irradiated to the high temperature region of the melt 300 is effectively reduced, and the temperature at the edge of the melt 300 is reduced, so that the oxygen content of the melt is decreased, and the quality of the ingot is enhanced.

In some embodiments, thermal field simulation in S1 may select an ingot growth phase for thermal field simulation. Parameters of thermal field simulation may use parameters in the ingot growth phase, so that the simulation result is more in line with the actual application.

In some embodiments, in S1, the semi-finished crucible product 101 is configured to pull a crystal by means of a Czochralski technique for thermal field simulation, to obtain a plurality of isotherms R in S2. The plurality of isotherms R are arranged from top to bottom with the decreasing of a liquid level of the melt 300. Regions on a wall of the semi-finished crucible product 101 corresponding to the plurality of isotherms R are cutting region. S3 further includes determining a position of the cutting portion 10 in the cutting region.

In some embodiments, as shown in the figure, the step of determining the position of the cutting portion 10 in the cutting region includes: importing the isotherm R into a drawing of the semi-finished crucible product 101, to determine the cutting region; and selecting a part of the plurality of isotherms R, and determining the position of the cutting portion 10 according to the position of the selected isotherm R. For example, the plurality of cutting portions 10 is in one-to-one correspondence with the upper end portions of the plurality of selected isotherms R, so as to accurately determine the positions of the cutting portions 10 and the grooves 1b.

For example, the isotherm R is imported into a CAD drawing of the semi-finished crucible product according to a proportion of 1:1, then a coordinate of any point on the isotherm R is an actual coordinate of the point, so that the cutting region is rapidly determined according to the positions of the plurality of isotherms R. Therefore, it is simple and convenient by means of rationally selecting the plurality of isotherms R to determine the position of the cutting portion 10. It is understood that, a specific temperature value represented by the selected isotherm R is selected according to an actual requirement.

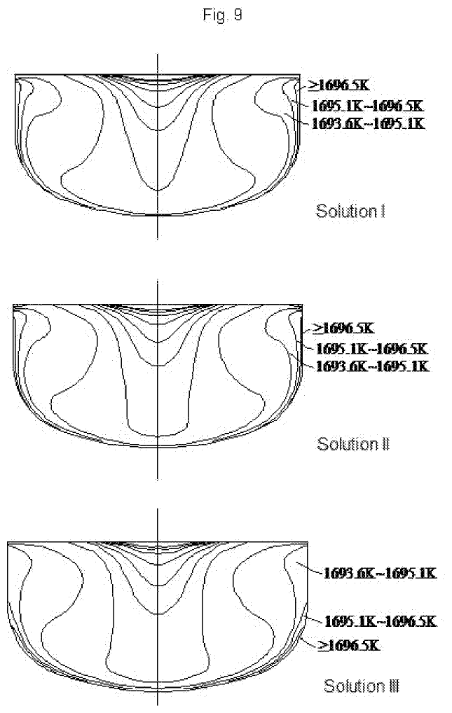

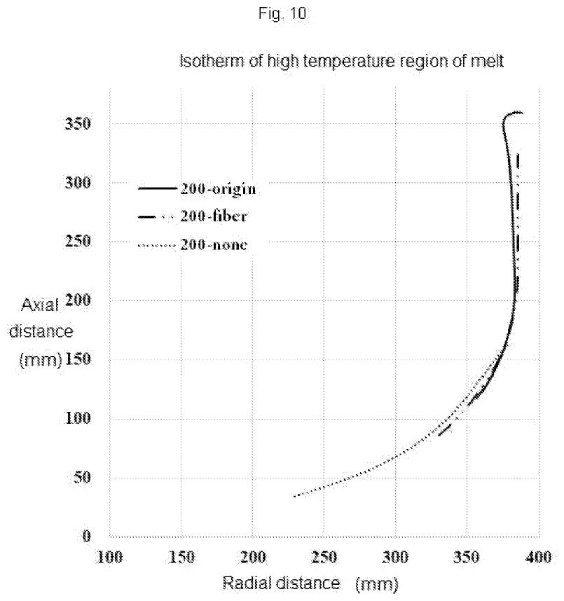

FIG. 9 and FIG. 10 show schematic diagrams of results of thermal field simulation performed on a semi-finished crucible product 101 (that is, Solution I, without disposing a groove 1b), a graphite crucible 100 (Solution II) that is provided with the groove 1b and a thermal insulation member filled in the groove 1b in the disclosure, and a graphite crucible 100 (Solution III) that is provided with the groove 1b and not filled with a material member in the groove 1b in the disclosure. In FIG. 10, “200-origin” corresponds to Solution I; “200-fiber” corresponds to Solution II; and “200-none” corresponds to Solution III. FIG. 10 shows the isotherms of the high temperature region of the melt of three solutions in FIG. 9. By means of comparison, it is seen that, according to Solution II and Solution III in the disclosure, the high temperature (≥1696.5K) region is significantly reduced compared with Solution I, and Solution III is more obvious, and the high temperature region moves downward and only a small part falls at the cutting portion, so that heat is effectively reduced and prevented from transferring to the melt by means of a vacuum groove. Definitely, the groove 1b effectively reduces the heat transferred to the melt 300.

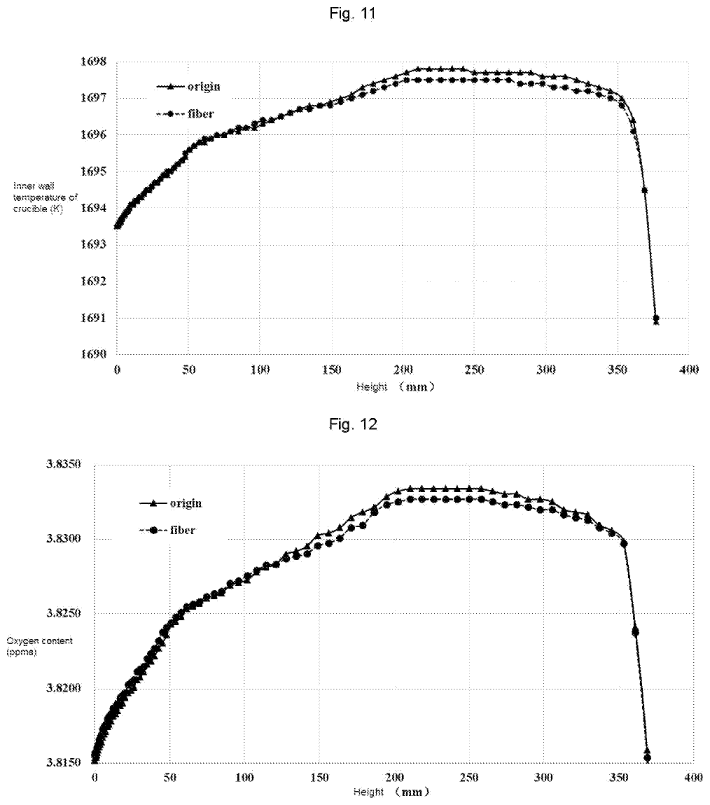

FIG. 11 and FIG. 12 show comparison of distribution of the inner wall temperature of the crucibles of the semi-finished crucible product (that is, Solution I, without disposing the groove 1b) and the thermal insulation member (Solution II) filed in the groove 1b and comparison of the oxygen content at the edge of the melt. It is obviously seen that, compared with Solution I, the temperature of the high temperature region in Solution II is reduced by 1-2° C., the oxygen content at the edge of the melt 300 is reduced accordingly, so that there is a significant correlation between the temperature in the high temperature region and the oxygen release from the crucible.

In the description of the disclosure, it is to be noted that, terms such as “center”, “longitudinal”, “transverse”, “thickness”, “up”, “down”, “vertical”, “horizontal”, “top”, “bottom”, “inside”, “outside”, “axial”, “radial”, “circumferential” and the like are orientation or position relationships shown in the drawings, are adopted not to indicate or imply that indicated apparatuses or components must be in specific orientations or structured and operated in specific orientations but only to conveniently describe the disclosure and simplify descriptions, and thus should not be construed as limits to the disclosure. Furthermore, features delimited with “first”, “second” may expressly or implicitly include one or more of that feature.

In the description of the disclosure, it is to be noted that, unless otherwise clearly specified and limited, the terms “mounted”, “connected” and “connect” should be interpreted broadly. For example, the term “connect” is fixed connection, detachable connection or integral construction. As an alternative, the term “connect” is mechanical connection, or electrical connection. As an alternative, the term “connect” is direct connection, or indirect connection through a medium, or communication in two elements. For those of ordinary skill in the art, specific meanings of the above mentioned terms in the disclosure is understood according to a specific condition.

In the description of the specification, descriptions of the terms “an embodiment,” “some embodiments,” “exemplary implementation,” “example,” “specific example,” or “some examples”, mean that specific features, structures, materials, or characteristics described with reference to the implementations or examples are included in at least one implementation or example of the disclosure. In this specification, schematic representations of the above terms do not necessarily refer to the same embodiment or example. In addition, the described particular features, structures, materials or characteristics are combined in any suitable manner in any one or more embodiments or examples.

Although the embodiments of the disclosure have been shown and described above, it is understood by those skilled in the art that various changes, modifications, replacements and variations is made in these embodiments without departing from the principle and objective of the disclosure, and the scope of the disclosure is defined by the claims and equivalents thereof.

What is claimed is:

1. A graphite crucible for a mono-crystal furnace, comprising:
a main body, wherein the main body is a graphite member and provided with a containing cavity; a wall of the containing cavity is provided with a cutting portion;
a groove is formed in the cutting portion, and extends in a circumferential direction of the main body to form an annular structure;
thermal field simulation is performed on a semi-finished crucible product, a quartz crucible matching the semi-finished crucible product, and a melt contained in the quartz crucible, to obtain an isotherm of a high temperature region of the melt; a shape of the groove is consistent with a shape of a part of the isotherm in a longitudinal section of the main body; the semi-finished crucible product is constructed to process the groove in an inner wall of the semi-finished crucible product so as to form the main body; and a temperature of the high temperature region is higher than a temperature of any other region of the melt.

2. The graphite crucible for a mono-crystal furnace according to claim 1, configured to pull a crystal by means of a Czochralski technique, wherein during crystal pulling, a plurality of isotherms are arranged from top to bottom with the decreasing of a liquid level of the melt; region on the wall of the semi-finished crucible product corresponding to the plurality of isotherms are cutting region; and a plurality of cutting portions are located in the cutting region.

3. The graphite crucible for a mono-crystal furnace according to claim 2, wherein the plurality of cutting portions are spaced apart from each other in an axial direction of the main body, and respectively correspond to the plurality of isotherms; each cutting portion of the plurality of cutting portions is formed with the groove; and the shape of the groove is consistent with the shape of the part of the corresponding isotherm of the plurality of isotherms.

4. The graphite crucible for a mono-crystal furnace according to claim 3, wherein the cutting portion is flush with an upper end portion of the corresponding isotherm of the plurality of isotherms.

5. The graphite crucible for a mono-crystal furnace according to claim 1, wherein the main body comprises a sidewall portion and a bottom wall portion; the sidewall portion is formed into a cylindric structure; the bottom wall portion is connected to a bottom of the sidewall portion to close the bottom of the sidewall portion; and the groove is formed in the sidewall portion and/or the bottom wall portion.

6. The graphite crucible for a mono-crystal furnace according to claim 5, wherein a thermal insulation member is filled in the groove; and thermal conductivity of the thermal insulation member is lower than thermal conductivity of the main body.

7. The graphite crucible for a mono-crystal furnace according to claim 6, wherein the thermal insulation member is a carbon fiber material member.

8. The graphite crucible for a mono-crystal furnace according to claim 1, wherein the shape of the groove is consistent with a shape of the upper end portion of the isotherm.

9. A crucible assembly, comprising:
a graphite crucible, wherein the graphite crucible is the graphite crucible for a mono-crystal furnace according to claim 1; and
a quartz crucible, mounted in the containing cavity of the graphite crucible.

10. A mono-crystal furnace, comprising:
a furnace body; and
a crucible assembly, wherein the crucible assembly is the crucible assembly according to claim 9 and is disposed in the furnace body.

11. A method for manufacturing a graphite crucible, wherein the graphite crucible is the graphite crucible for a mono-crystal furnace according to claim 1; and the manufacturing method comprises the following steps:
S1: performing thermal field simulation on the semi-finished crucible product, the quartz crucible matching the semi-finished crucible product, and the melt contained in the quartz crucible;
S2: extracting a simulation result in S1, to obtain the isotherm of the high temperature region of the melt, wherein the temperature of the high temperature region is higher than the temperature of any other region of the melt; and
S3: determining the shape of the groove on the longitudinal section of the semi-finished crucible product according to the shape of the isotherm, and processing the groove in a cutting portion to form the main body.

12. The method for manufacturing a graphite crucible according to claim 11, wherein in S1, the semi-finished crucible product is configured to pull a crystal by means of a Czochralski technique for thermal field simulation, to obtain a plurality of isotherms in S2; the plurality of isotherms are arranged from top to bottom with the decreasing of a liquid level of the melt; region on a wall of the semi-finished crucible product corresponding to the plurality of isotherms are cutting region; and
S3 further comprises determining a position of the cutting portion in the cutting region.

13. The method for manufacturing a graphite crucible according to claim 12, wherein the determining a position of the cutting portion in the cutting region comprises:
importing the plurality of isotherms into a drawing of the semi-finished crucible product, to determine the cutting region; and
selecting a part of the plurality of isotherms, and determining the position of the cutting portion according to the position of the selected isotherm of the plurality of isotherms.

14. The method for manufacturing a graphite crucible according to claim 11, wherein configured to pull a crystal by means of a Czochralski technique, wherein during crystal pulling, a plurality of isotherms are arranged from top to bottom with the decreasing of a liquid level of the melt; region on the wall of the semi-finished crucible product corresponding to the plurality of isotherms are cutting region; and a plurality of cutting portions are located in the cutting region.

15. The method for manufacturing a graphite crucible according to claim 14, wherein the plurality of cutting portions are spaced apart from each other in an axial direction of the main body, and respectively correspond to the plurality of isotherms;
each cutting portion of the plurality of cutting portions is formed with the groove; and
the shape of the groove is consistent with the shape of the part of the corresponding isotherm of the plurality of isotherms.

16. The method for manufacturing a graphite crucible according to claim 15, wherein the cutting portion is flush with an upper end portion of the corresponding isotherm of the plurality of isotherms.

17. The method for manufacturing a graphite crucible according to claim 11, wherein the main body comprises a sidewall portion and a bottom wall portion; the sidewall portion is formed into a cylindric structure; the bottom wall portion is connected to a bottom of the sidewall portion to close the bottom of the sidewall portion; and the groove is formed in the sidewall portion and/or the bottom wall portion.

18. The method for manufacturing a graphite crucible according to claim 17, wherein a thermal insulation member is filled in the groove; and thermal conductivity of the thermal insulation member is lower than thermal conductivity of the main body.

19. The method for manufacturing a graphite crucible according to claim 18, wherein the thermal insulation member is a carbon fiber material member.

20. The method for manufacturing a graphite crucible according to claim 11, wherein the shape of the groove is consistent with a shape of the upper end portion of the isotherm.
